(19) United States
(12) Patent Application Publication
(10) Pub. No.: US 2024/0413084 A1
(43) Pub. Date: Dec. 12, 2024

(54) STACKED FETs WITH BACKSIDE ANGLE CUT

(71) Applicant: International Business Machines Corporation, Armonk, NY (US)

(72) Inventors: Ruilong Xie, Niskayuna, NY (US); Koichi Motoyama, Clifton Park, NY (US); Nicholas Anthony Lanzillo, Wynantskill, NY (US); Sagarika Mukesh, ALBANY, NY (US)

(21) Appl. No.: 18/332,388

(22) Filed: Jun. 9, 2023

(51) Int. Cl. H01L 23/528; H01L 21/822; H01L 21/8238; H01L 27/092; H01L 29/06; H01L 29/417; H01L 29/423; H01L 29/66; H01L 29/775

(52) U.S. Cl. CPC H01L 23/5286; H01L 21/8221; H01L 21/823807; H01L 21/823871; H01L 27/0922; H01L 29/0673; H01L 29/41733; H01L 29/42392; H01L 29/66439; H01L 29/775

(57) ABSTRACT

A semiconductor structure is provided that includes a first stacked FET cell including a second FET stacked over a first FET, and a second stacked FET cell located adjacent to the first stacked FET cell and including a fourth FET stacked over a third FET. The structure further includes a first backside source/drain contact structure located beneath the first stacked FET cell and contacting a source/drain region of the first FET, a second backside source/drain contact structure located beneath the second stacked FET cell and contacting a source/drain region of the third FET, and an angled cut region laterally separating the first backside source/drain contact structure from the second backside source/drain contact structure.

### BACKGROUND

The present application relates to semiconductor technology, and more particularly to a semiconductor structure including stacked field effect transistors (FETs) having improved cell height scaling.

Stacking of FETs is an attractive architecture for future complementary metal oxide semiconductor (CMOS) scaling, and potentially for ultimately scaled technology. By directly stacking FETs one over the other (for example, pFETs over nFETs, nFETs over pFETs, pFETs over pFETs, or nFETs over nFETs) significant area scaling can be achieved.

### SUMMARY

In one aspect of the present application, a semiconductor structure is provided. In one embodiment of the present application, the semiconductor structure includes a first stacked FET cell including a second FET stacked over a first FET. The structure further includes a second stacked FET cell located adjacent to the first stacked FET cell and including a fourth FET stacked over a third FET. The structure even further includes a first backside source/drain contact structure located beneath the first stacked FET cell and contacting a source/drain region of the first FET, a second backside source/drain contact structure located beneath the second stacked FET cell and contacting a source/drain region of the third FET, and an angled cut region laterally separating the first backside source/drain contact structure from the second backside source/drain contact structure.

### BRIEF DESCRIPTION OF THE DRAWINGS

FIG. 1 is a top down view of a device layout that can be employed in the present application, the device layout including a plurality of gate structures that are oriented perpendicular to different active areas; the illustrated device layout includes cut A-A, cut B-B, and cut C-C.

FIGS. 2A, 2B and 2C are cross sectional views through cut A-A, cut B-B and cut C-C, respectively, of an exemplary semiconductor structure that can be employed in the present application, the exemplary structure including a substrate, a first placeholder material layer located on the substrate, a first material stack located on the first placeholder material layer, a second placeholder material layer located on the first material stack, a second material stack located on the second placeholder material layer, and a plurality of sacrificial gate structures located on the second material stack.

FIGS. 3A, 3B and 3C are cross sectional views of the exemplary semiconductor structure shown in FIGS. 2A, 2B and 2C, respectively, after removing the first placeholder material layer and second placeholder material layer, depositing a dielectric material to form a gate spacer, a bottom dielectric isolation layer and a device isolation layer, patterning the second material stack, the device isolation layer and the first material stack, and forming an inner spacer, these steps form a plurality of patterned nanosheet containing structures including a second nanosheet material stack located over a first nanosheet material stack.

FIGS. 4A, 4B and 4C are cross sectional views of the exemplary semiconductor structure shown in FIGS. 3A, 3B and 3C, respectively, after forming openings into an upper portion of the substrate.

FIGS. 5A, 5B and 5C are cross sectional views of the exemplary semiconductor structure shown in FIGS. 4A, 4B and 4C, respectively, after forming a sacrificial material structure in each of the openings, forming bottom source/drain regions, a first frontside interlayer dielectric layer, top source/drain regions, and a second frontside interlayer dielectric layer, removing each sacrificial gate structure, removing each first sacrificial semiconductor material nanosheet of the first nanosheet material stacks and each second sacrificial semiconductor material nanosheet of the second nanosheet material stacks, and forming a gate structure wrapped around each first semiconductor channel material nanosheet of the first nanosheet material stacks and each second semiconductor channel material nanosheet of the second nanosheet material stacks.

FIGS. 6A, 6B and 6C are cross sectional views of the exemplary semiconductor structure shown in FIGS. 5A, 5B and 5C, respectively, after forming a third frontside interlayer dielectric layer (collectively, the second frontside interlayer dielectric layer and the third frontside interlayer dielectric layer provide a middle-of-the-line (MOL) dielectric layer), and cutting at least one gate structure.

FIGS. 7A, 7B and 7C are cross sectional views of the exemplary semiconductor structure shown in FIGS. 6A, 6B and 6C, respectively, after forming a bi-layered dielectric structure including an outer dielectric liner and an inner dielectric plug in each opening created by the cutting of the at least one gate structure.

FIGS. 8A, 8B and 8C are cross sectional views of the exemplary semiconductor structure shown in FIGS. 7A, 7B and 7C, respectively, after forming deep via openings in the structure by removing the inner dielectric plug from some of the bi-layered dielectric structures.

FIGS. 9A, 9B and 9C are cross sectional views of the exemplary semiconductor structure shown in FIGS. 8A, 8B and 8C, respectively, after forming frontside contact openings into the MOL dielectric layer.

FIGS. 10A, 10B and 10C are cross sectional views of the exemplary semiconductor structure shown in FIGS. 9A, 9B and 9C, respectively, after forming frontside contact structures and deep vias, an initial frontside back-end-of-line (BEOL) structure including lower interconnect levels, an additional frontside BEOL structure, and a carrier wafer.

FIGS. 11A, 11B and 11C are cross sectional views of the exemplary semiconductor structure shown in FIGS. 10A, 10B and 10C, respectively, after removing a first semiconductor layer of the substrate to expose an etch stop layer of the substrate.

FIGS. 12A, 12B and 12C are cross sectional views of the exemplary semiconductor structure shown in FIGS. 11A, 11B and 11C, respectively, after removing the etch stop layer and a second semiconductor layer of the substrate.

FIGS. 13A, 13B and 13C are cross sectional views of the exemplary semiconductor structure shown in FIGS. 12A, 12B and 12C, respectively, after forming a first backside interlayer dielectric layer.

FIGS. 14A, 14B and 14C are cross sectional views of the exemplary semiconductor structure shown in FIGS. 13A, 13B and 13C, respectively, after removing each sacrificial material structure and forming backside source/drain contact structures.

FIGS. 15A, 15B and 15C are cross sectional views of the exemplary semiconductor structure shown in FIGS. 14A, 14B and 14C, respectively, after performing a backside angle cut of one of the backside source/drain contact structures.

FIGS. 16A, 16B and 16C are cross sectional views of the exemplary semiconductor structure shown in FIGS. 15A, 15B and 15C, respectively, after forming an initial backside BEOL structure including lower interconnect levels.

FIGS. 17A, 17B and 17C are cross sectional views of the exemplary semiconductor structure shown in FIGS. 16A, 16B and 16C, respectively, after forming an additional backside BEOL structure.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

In stacked FETs, backside power rails and backside power distribution networks can greatly improve the routablity of the stacked FETs. However, when backside contacts need to be wired not only to the backside interconnects, but also to the frontside interconnects, the space for the routing can become tight. The present application address this issue.

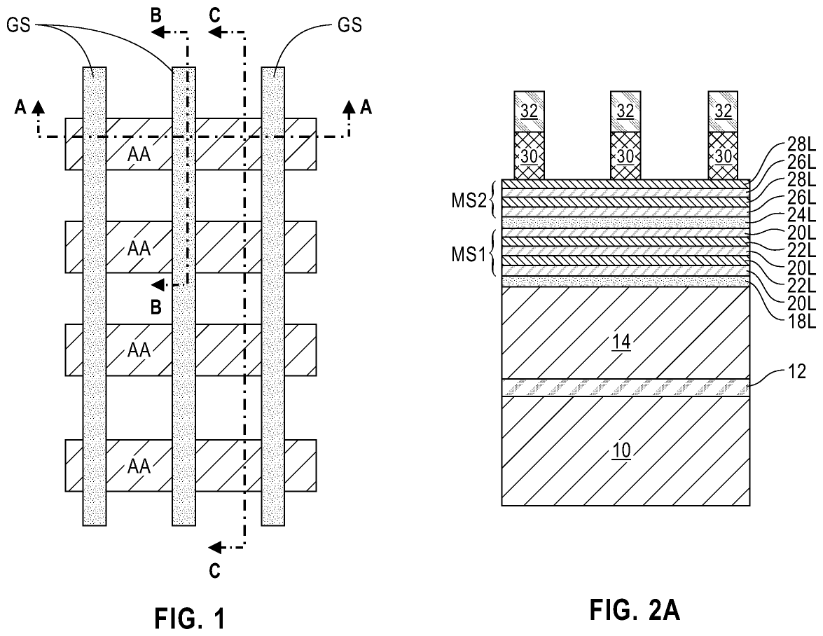

Referring first to FIG. 1, there is illustrated a device layout that can be employed in the present application. The illustrated device layout includes a plurality of gate structures, GS, which are oriented perpendicular to different active areas, AA. In the illustrated device layout, three gate structures, GS, and four device areas, AA, are shown by way of one example. The illustrated device layout of FIG. 1 includes cut A-A, cut B-B, and cut C-C. Cut A-A is through a length-wise direction of one of the active areas, AA, cut B-B is partially through a length-wise direction of one of the gate structures, GS, and cut C-C is located in between two neighboring gate structures, GS, and it passes through source/drain (S/D) regions of the two neighboring gate structures, GS.

In the present application, a semiconductor structure is described and illustrated as containing stacked nanosheet transistors. A transistor includes a source region, a drain region, a semiconductor channel region located between the source region and the drain region, and a gate electrode located above the semiconductor channel region. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure including a gate dielectric and a gate electrode wraps around each of the spaced apart semiconductor channel material nanosheets. Although stacked nanosheet transistors are described and illustrated, the present application can used with stacked planar transistors, or other stacked non-planar transistors such as, for example, semiconductor nanowire transistors or finFET transistors.

In the present application, the semiconductor structure includes a frontside and a backside. The frontside of the semiconductor structure of the present application includes a side of the structure that includes the transistors, MOL level, and all frontside BEOL structures. The backside of the semiconductor structure of the present application is the side of the structure that is opposite the frontside. In a stacked nanosheet transistor, the frontside can be located on a first side of a bottom dielectric isolation layer, while the backside can be located on a second side of the bottom dielectric isolation layer that is opposite the first side.

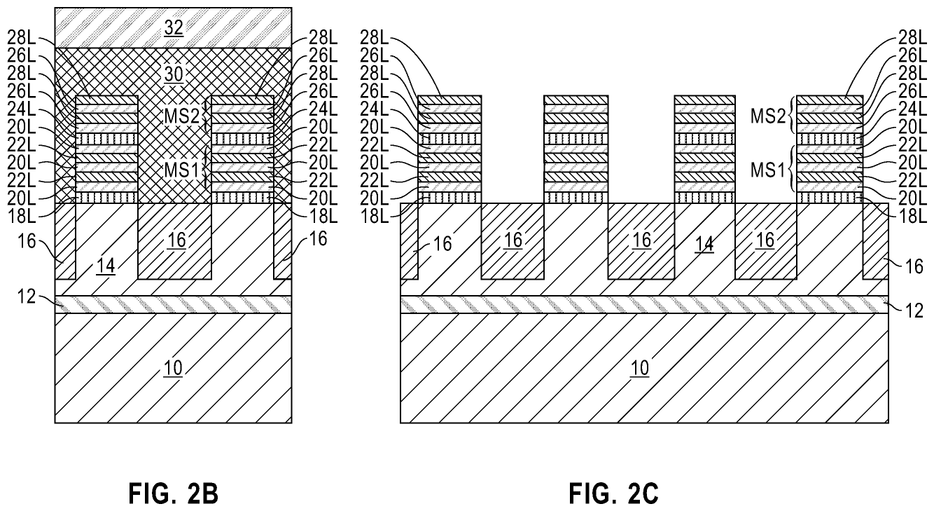

Referring now to FIGS. 2A, 2B and 2C, there are illustrated an exemplary structure that can be employed in the present application; FIG. 2A is a cross sectional view through cut A-A shown in FIG. 1, FIG. 2B is a cross sectional view through cut B-B shown in FIG. 1 and FIG. 2C is a cross sectional view through cut C-C shown in FIG. 1. The illustrated structure shown in FIGS. 2A-2C includes a substrate (10/12/14), a first placeholder material layer 18L located on the substrate (10/12/14), a first material stack, MS1, located on the first placeholder material layer 18L, a second placeholder material layer 24L located on the first material stack, MS1, a second material stack, MS2, located on the second placeholder material layer 24L, and a plurality of sacrificial gate structures 30 (three of which are shown by way one example in FIG. 2A) located on the second material stack, MS2. Each sacrificial gate structure 30 can be capped with a sacrificial gate cap 32. Each sacrificial gate structure 30 is present on a topmost surface of the second material stack, MS2, and along a sidewall of each of the first placeholder material layer 18L, the first material stack, MS1, the second placeholder material layer 24L, and the second material stack, MS2. In some embodiments, the sacrificial gate cap 32 can be omitted. In the illustrated embodiment shown in FIGS. 2A-2C, shallow trench isolation structures 16 are present in an upper portion of the substrate (10/12/14). The shallow trench isolation structures 16 would be located in the region of the device layout shown in FIG. 1 that is located between each of the active areas, AA.

The semiconductor structure illustrated in FIGS. 2A-2C can be formed utilizing various processing steps that are well known to those skilled in the art. The processing steps can include, for example, various deposition and patterning steps. The depositions can include, but are not limited to, chemical vapor deposition (CVD), plasma enhanced chemical vapor deposition (PECVD), physical vapor deposition (PVD), and atomic layer deposition (ALD). In some embodiments, an epitaxial growth process (as defined later herein) can be used to form semiconductor materials that are present in the illustrated semiconductor structure. Patterning can include lithography and etching (dry etching and/or chemical wet etching). Dry etching can include, for example, reactive ion etching (RIE), ion beam etching (IBE), and plasma etching. Chemical wet etching includes the use of an appropriate chemical etchant that has a high etch rate for one material as compared to at least one another material. So as not to obscure the method of the present application, the processing steps used in providing the structure shown in FIGS. 2A-2C have been omitted from this application. Each of the elements/components of the structure illustrated in FIGS. 2A-2C will now be described in greater detail.

In some embodiments, and as illustrated in FIGS. 2A-2C, the substrate can include a first semiconductor layer 10, an etch stop layer 12 and a second semiconductor layer 14. In other embodiments, the etch stop layer 12 and the second semiconductor layer 14 can be omitted and in such embodiments, the substrate is composed of the first semiconductor layer 10. In yet other embodiments, the etch stop layer 12 can be omitted and in such embodiments, the substrate is composed of the first semiconductor layer 10 and the second semiconductor layer 14 (in such embodiments the semiconductor material that provides the first and second semiconductor layers 10, 14 are compositionally different from each other).

The first semiconductor layer 10 is composed of a first semiconductor material. The second semiconductor layer 14 is composed of a second semiconductor material. The term “semiconductor material” is used throughout the present application to denote a material having semiconducting properties. Examples of semiconductor materials that can be used in the present application in providing the first semiconductor material and the second semiconductor material include, but are not limited to, silicon (Si), a silicon germanium (SiGe) alloy, a silicon germanium carbide (SiGeC) alloy, germanium (Ge), III/V compound semiconductors or II/VI compound semiconductors. The second semiconductor material that provides the second semiconductor layer 14 can be compositionally the same as, or compositionally different from, the first semiconductor material that provides the first semiconductor layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the first semiconductor layer 10 and the second semiconductor material that provides the second semiconductor layer 14. In one example, the first semiconductor layer 10 is composed of silicon, the etch stop layer 12 is composed of silicon dioxide, and the second semiconductor layer 14 is composed of silicon. In another example, the first semiconductor layer 10 is composed of silicon, the etch stop layer 12 is composed of silicon germanium, and the second semiconductor layer 14 is composed of silicon. The substrate including the first semiconductor layer 10, the etch stop layer 12 and the second semiconductor layer 14 can be formed utilizing techniques well known to those skilled in the art.

The shallow trench isolation structures 16 can be formed into the substrate; in the illustrated embodiment the shallow trench isolation structures 16 are formed into the second semiconductor layer 14. Each shallow trench isolation structure 16 is composed of a trench dielectric material such as, for example, silicon oxide. In some embodiments, a trench dielectric liner composed of, for example, SiN, can be present along a sidewall and a bottom wall of the trench dielectric material. Each shallow trench isolation structure 16 can have a topmost surface that is coplanar with a topmost surface of the non-etched portion of the substrate; in the illustrated embodiment each shallow trench isolation structure 16 can have a topmost surface that is coplanar with a topmost surface of the non-etched portion of the second semiconductor layer 14.

The first placeholder material layer 18L is composed of fourth semiconductor material that is compositionally different from the second semiconductor material that provides the second semiconductor layer 14 of the substrate (10/12/14). In one example, the fourth semiconductor material that provides the first placeholder material layer 18L is composed of a SiGe alloy including from 55 to 70 atomic percent germanium.

The first material stack, MS1, is composed of alternating layers of a first sacrificial semiconductor material layer 20L and a first semiconductor channel material layer 22L. In some embodiments and as is illustrated in FIGS. 2A-2C, there are “n+1” numbers of first sacrificial semiconductor material layers 20L and “n” number of first semiconductor channel material layers 22L, wherein n is an integer starting from one. Thus, each first semiconductor channel material layer 22L is sandwiched between a bottom and top first sacrificial semiconductor material layer 20L. By way of one example, the first material stack, MS1, includes three first sacrificial semiconductor material layers 20L and two first semiconductor channel material layers 22L. Each first sacrificial semiconductor material layer 20L is composed of a fifth semiconductor material, while each first semiconductor channel material layer 22L is composed of a sixth semiconductor material. In the present application, the sixth semiconductor material is compositionally different from the fifth semiconductor material, and both the fifth and sixth semiconductor materials are compositionally different from the fourth semiconductor material.

In some embodiments, the sixth semiconductor material that provides each first semiconductor channel material layer 22L is capable of providing high channel mobility for n-type field effect transistor (FET) devices. In other embodiments, the sixth semiconductor material that provides each first semiconductor channel material layer 22L is capable of providing high channel mobility for p-type FET devices. The fifth semiconductor material that provides each first sacrificial semiconductor material layer 20L, and the sixth semiconductor material that provides each first semiconductor channel material layer 22L can include one of the semiconductor materials mentioned above. In one example, each first sacrificial semiconductor material layer 20L is composed of a silicon germanium alloy having a germanium content from 20 atomic percent to 40 atomic percent, and each first semiconductor channel material layer 22L is composed of silicon. Other combinations of semiconductor materials are possible as long as the fifth semiconductor material that provides each first sacrificial semiconductor material layer 20L is compositionally different from the sixth semiconductor material that provides each first semiconductor channel material layer 22L, and that both the fifth and sixth semiconductor materials are different from the fourth semiconductor material.

Each first sacrificial semiconductor material layer 20L can have a first thickness, and each first semiconductor channel material layer 22L can have a second thickness. In the present application, the first thickness can be equal to, greater than, or less than, the second thickness.

The second placeholder material layer 24L is compositionally the same as the first placeholder material layer 18L. Thus, the second placeholder material layer 24L is composed of the fourth semiconductor material. In one example, the fourth semiconductor material that provides both the first placeholder material layer 18L and the second placeholder material layer 24L is composed of a SiGe alloy including from 55 to 70 atomic percent germanium.

The second material stack, MS2, is composed of alternating second sacrificial semiconductor material layers 26L and second semiconductor channel material layers 28L. In some embodiments and as is illustrated in FIGS. 2A-2C, there is an equal number of second sacrificial semiconductor material layers 26L and second semiconductor channel material layers 28L. That is, the material stack can include ‘y’ number of second semiconductor channel material layers 28L and ‘y’ number of second sacrificial semiconductor material layers 26L, wherein y is an integer starting from one. By way of one example, the second nanosheet material stack, MS2, includes two second sacrificial semiconductor material layers 26L and two second semiconductor channel material layers 28L. Each second sacrificial semiconductor material layer 26L is composed of a seventh semiconductor material, while each second semiconductor channel material layer 28L is composed of eighth semiconductor material; the eighth semiconductor material is compositionally different from the seventh semiconductor material. In the present application, the seventh semiconductor material is typically compositionally the same as the fifth semiconductor material, while the eighth semiconductor material can be compositionally the same as, or compositionally different from, the sixth semiconductor material. In the present application, the seventh and eighth semiconductor materials are compositionally different from the fourth semiconductor material.

In some embodiments, the eighth semiconductor material that provides each second semiconductor channel material layer 28L is capable of providing high channel mobility for n-type field effect transistor (FET) devices. In other embodiments, the eighth semiconductor material that provides each second semiconductor channel material layer 28L is capable of providing high channel mobility for p-type FET devices. The seventh and eighth semiconductor materials can include one of the semiconductor materials mentioned above.

In one embodiment, the first placeholder material layer 18L and the second placeholder material layer 24L are both composed of a SiGe alloy including from 55 to 70 atomic percent germanium, the first sacrificial semiconductor material layers 20L and the second sacrificial semiconductor material layers 26L are composed of a silicon germanium alloy having a germanium content from 20 atomic percent to 40 atomic percent, and the first semiconductor channel material layers 22L are composed of silicon, and the second semiconductor channel material layers 28L are composed of germanium.

Each second sacrificial semiconductor material layer 26L can have a third thickness, and each second semiconductor channel material layer 28L can have a fourth thickness. In the present application, the third thickness can be equal to, greater than, or less than, the fourth thickness. In the present application, the third and fourth thicknesses can be equal to, greater than, or less than the first thickness and/or the second thickness.

Each sacrificial gate structure 30 includes at least a sacrificial gate material. In some embodiments, each sacrificial gate structure 30 can also include a sacrificial gate dielectric material. In such embodiments, the sacrificial gate dielectric material would be located beneath the sacrificial gate material. The optional sacrificial gate dielectric material can be composed of a dielectric material such as, for example, silicon dioxide. The sacrificial gate material can be composed of, for example, polysilicon, amorphous silicon, amorphous silicon germanium or amorphous germanium.

The sacrificial gate cap 32 is composed of a hard mask material such as, for example, silicon nitride. In some embodiments, the sacrificial gate cap 32 can be omitted from on top of the sacrificial gate structure 30.

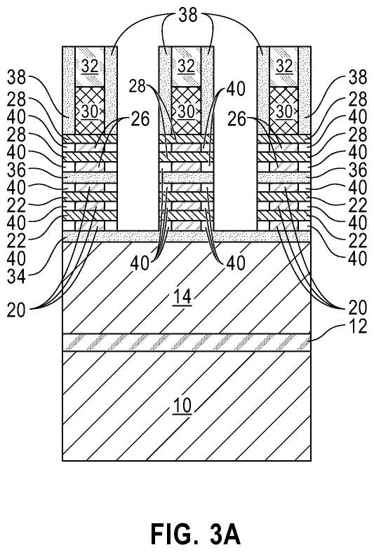

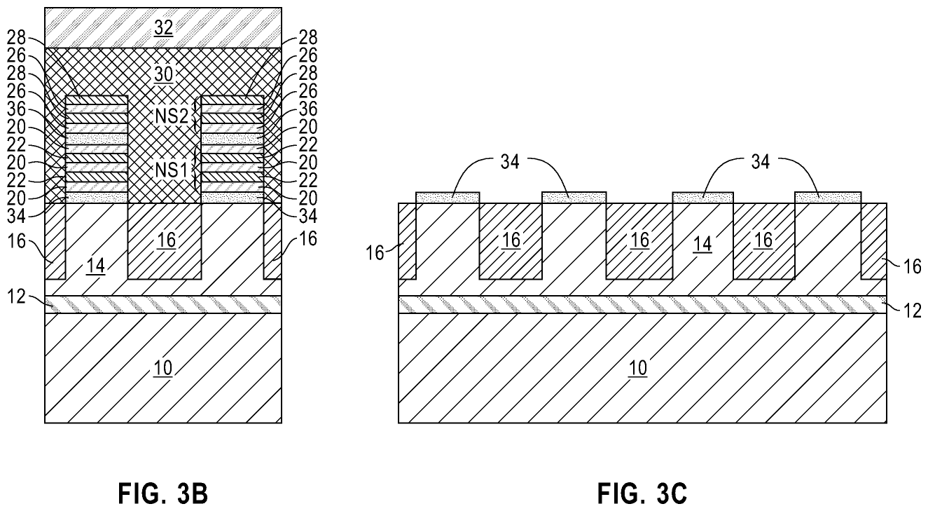

Referring now to FIGS. 3A, 3B and 3C, there are illustrated the exemplary semiconductor structure shown in FIGS. 2A, 2B and 2C, respectively, after removing the first placeholder material layer 18L and the second placeholder material layer 24L, depositing a dielectric material to form a gate spacer 38, a bottom dielectric isolation layer 34 and a device isolation layer 36, patterning the second material stack, MS2, the device isolation layer 36 and the first material stack, MS1, and forming an inner spacer 40, these steps form a plurality of patterned nanosheet containing structures including a second nanosheet material stack, NS2, located over a first nanosheet material stack, NS1.

The removal of the first placeholder material layer 18L and the second placeholder material layer 24L can be performed utilizing a selective etching process. This removal forms a first cavity beneath the first material stack, MS1, and a second cavity between the second material stack, MS2, and the first material stack, MS2. During this removal process, the structure is anchored by the sacrificial gate structures 30, and if present, the sacrificial gate caps 32.

After forming the first and second cavities mentioned above, a dielectric material is formed to provide the gate spacer 38 along a sidewall of each sacrificial gate structure 30, the bottom dielectric isolation layer 34 (in the first cavity beneath the first material stack, MS1) and the device isolation layer 36 (in the second cavity that is located between the second material stack, MS2, and the first material stack, MS1. The dielectric material used in forming the bottom dielectric isolation layer 34, the device isolation layer 36, and the gate spacer 38 includes, but is not limited to, silicon dioxide, SiN, SiBCN, SiOCN or SiOC. The dielectric material can be formed utilizing a deposition process including, for example, CVD, PECVD or ALD.

The patterning step employed in providing the structure illustrated in FIGS. 3A-3C includes an etch such as, for example, a RIE, in which each gate spacer 38, sacrificial gate structure 30 and, if present, the sacrificial gate cap 32 serve as an etch mask. The etch removes portions of the second material stack, MS2, (including portions of each second sacrificial semiconductor material layer 26L and each second semiconductor channel material layer 28L), portions of the device isolation layer 36, portions of the first material stack, MS1, (including portions of each first sacrificial semiconductor material layer 20L and each first semiconductor channel material layer 22L), and portions of the bottom dielectric isolation layer 34 that are not protected by the etch mask. After this patterning steps, a portion of the second material stack, MS2, (including a portion of each second sacrificial semiconductor material layer 26L and each second semiconductor channel material layer 28L), a portion of the device isolation layer 36, and a portion of the first material stack, MS1, (including a portion of each first sacrificial semiconductor material layer 20L and each first semiconductor channel material layer 22L) remain beneath the etch mask. The etch used in this patterning step stops on the bottom dielectric isolation layer 34.

The portion of the second material stack, MS2, that remains beneath each sacrificial gate structure 30 can be referred to as a second nanosheet material stack, NS2. Each second nanosheet material stack, NS2, includes unetched portions of each second sacrificial semiconductor material layer 26L and each second semiconductor channel material layer 28L. The unetched portion of each second sacrificial semiconductor material layer 26L can be referred to herein as a second sacrificial semiconductor material nanosheet 26, and the unetched portion of each second semiconductor channel material layer 28L can be referred to as a second semiconductor channel material nanosheet 28.

The portion of the first material stack, MS1, that remains beneath each sacrificial gate structure 30 can be referred to as a first nanosheet material stack, NS1. Each first nanosheet material stack, NS1, includes unetched portions of each first sacrificial semiconductor material layer 20L and each first semiconductor channel material layer 22L. The unetched portion of each first sacrificial semiconductor material layer 20L can be referred to herein as a first sacrificial semiconductor material nanosheet 20, and the unetched portion of each first semiconductor channel material layer 22L can be referred to as a first semiconductor channel material nanosheet 22.

In the present application, each nanosheet has a length along the A-A cut that is less than the length of each of the original first sacrificial semiconductor material layers 20L, original first semiconductor channel material layers 22L, original second sacrificial semiconductor layers 26L, and original second semiconductor channel material layers 28L.

As is illustrated, an individual second nanosheet material stack, NS2 is stacked above, one of the first nanosheet material stacks, NS1. Collectively, each stacked NS1 and NS2 configuration can be referred to as a patterned nanosheet containing structure.

After the patterning process mentioned above, each first sacrificial semiconductor material nanosheet 20 and each second sacrificial semiconductor material nanosheet 26 is subjected to a lateral etch that removes end portions each of first sacrificial semiconductor material nanosheet 20 and each second sacrificial semiconductor material nanosheet 26. The lateral etch can include a single lateral etching process or two different lateral etching process can be used. The inner spacer 40 is then formed at the ends of each first sacrificial semiconductor material nanosheet 20 and each second sacrificial semiconductor material nanosheet 26 that were subjected to the lateral etch. The inner spacer 40 is composed of one of dielectric materials mentioned above for providing the bottom dielectric isolation layer 34, the device isolation layer 36, and the gate spacer 38. The dielectric material that provides each inner spacer 40 can be compositionally the same as, or compositionally different from, the dielectric material that provides the bottom dielectric isolation layer 34, the device isolation layer 36, and the gate spacer 38. Inner spacer 40 can be formed by a deposition process, followed by a spacer etch.

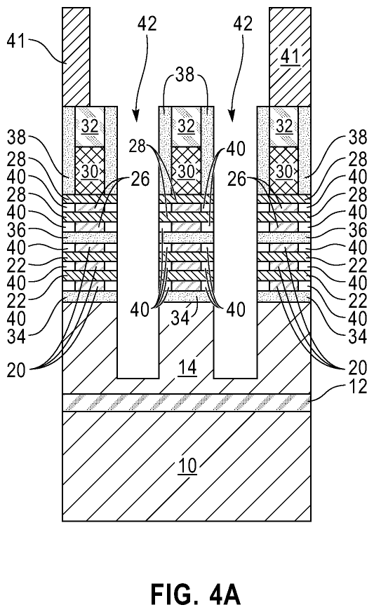

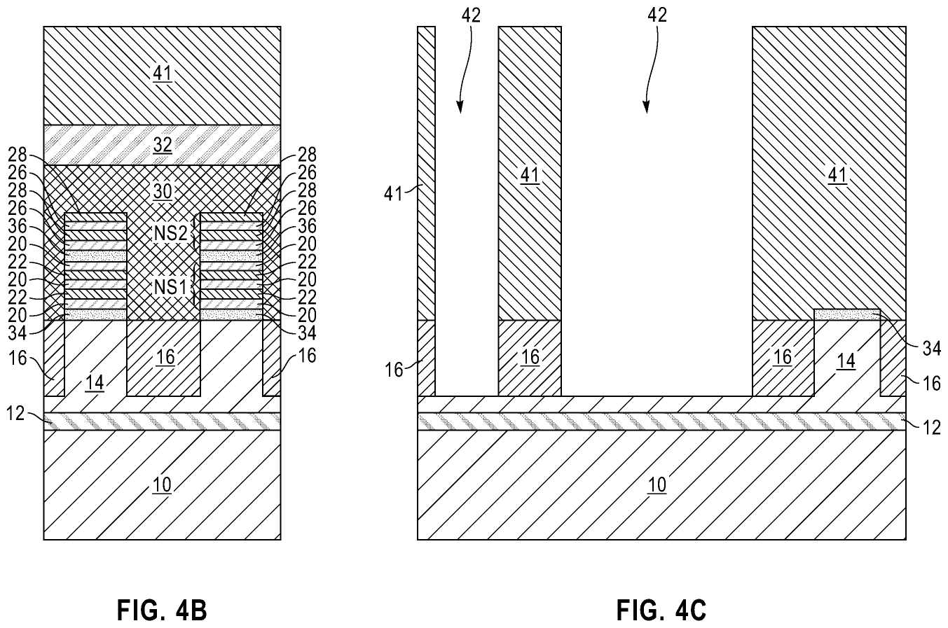

Referring now to FIGS. 4A, 4B and 4C, there are illustrated the exemplary semiconductor structure shown in FIGS. 3A, 3B and 3C, respectively, after forming openings 42 into an upper portion of the substrate (10/12/14); in the illustrated embodiment the openings 42 are formed into the second semiconductor layer 14 and can remove one of the shallow trench isolation structures 16 from the structure. The openings 42 can be formed by first forming an organic planarization layer (OPL) 41 utilizing a deposition process (e.g., CVD, PECVD or spin-on coating), patterning the OPL 41 by lithography and etching, and thereafter transferring the pattern formed into the OPL layer 41 utilizing a transfer etching process. The transfer etching process removes physically exposed portions of the bottom dielectric isolation layer 34, the shallow trench isolation structure 16 (in some areas) and upper portion of the substrate (10/12/14); in the illustrated embodiment an upper portion of the second semiconductor layer 14 is removed by this transfer etching process.

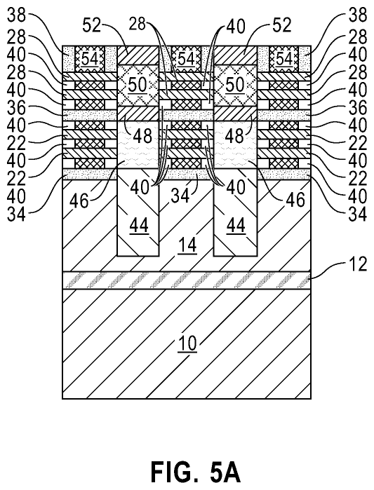

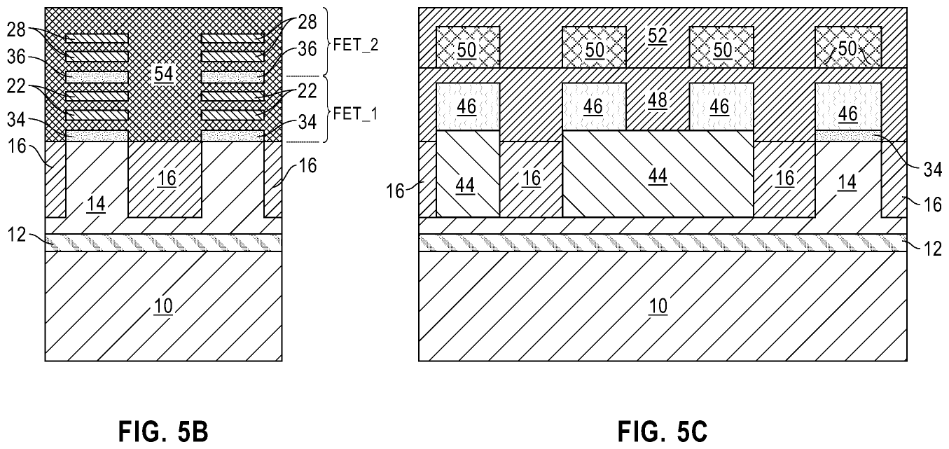

After forming the openings 42 and prior to performed the processing steps illustrated in FIGS. 5A-5C, the remaining OPL 41 can be removed from the structure utilizing any material removal process that is selective in removing the OPL 41 from the structure.

Referring now to FIGS. 5A, 5B and 5C, there are illustrated the exemplary semiconductor structure shown in FIGS. 4A, 4B and 4C, respectively, after forming a sacrificial material structure 44 in each of the openings 42, forming bottom source/drain regions 46, a first frontside interlayer dielectric (ILD) layer 48, top source/drain regions 50, and a second frontside ILD layer 52, removing each sacrificial gate structure 30, removing each first sacrificial semiconductor material nanosheet 20 and each second sacrificial semiconductor material nanosheet 26, and forming a gate structure 54 wrapped around each first semiconductor channel material nanosheet 22 and each second semiconductor channel material nanosheet 28.

The sacrificial material structure 44 can be formed by deposition of a dielectric material, followed by a recess etch to reduce the height of the deposited dielectric material. Illustrative examples of dielectric materials that can be used in providing the sacrificial material structure 44 include, but are not limited to, SiC, SiOC or AlOₓ.

The bottom source/drain regions 46 are typically formed by an epitaxial growth process. Throughout the present application, the terms “epitaxial growth” or “epitaxially growing” mean the growth of a semiconductor material on a growth surface of another semiconductor material, in which the semiconductor material being grown has the same crystalline characteristics as the growth surface of the another semiconductor material. In an epitaxial deposition process, the chemical reactants provided by the source gases are controlled and the system parameters are set so that the depositing atoms arrive at the growth surface of the another semiconductor material with sufficient energy to move around on the growth surface and orient themselves to the crystal arrangement of the atoms of the growth surface. Examples of various epitaxial growth process apparatuses that can be employed in the present application include, e.g., rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition typically ranges from 550° C. to 900° C. Although higher temperature typically results in faster deposition, the faster deposition may result in crystal defects and film cracking. Following the epitaxial growth process, a recess etch can be used to reduce the height of the bottom source/drain regions. The bottom source/drain regions 46 do not extend above the bottommost layer of the device isolation layer 36.

The bottom source/drain regions 46 extend outward from a sidewall of each first semiconductor channel material nanosheet 22. The bottom source/drain regions 46 are located on an upper surface of the sacrificial material structure 44 or an upper surface of bottom dielectric isolation layer 34. Each of the bottom source/drain regions 46 is composed of a semiconductor material and a first dopant. As used herein, a “source/drain” region can be a source region or a drain region depending on subsequent wiring and application of voltages during operation of the transistor. The semiconductor material that provides each bottom source/drain region 46 is composed of one of the semiconductor materials mentioned above for the first semiconductor layer 10. The semiconductor material that provides the bottom source/drain regions 46 can be compositionally the same, or compositionally different from each first semiconductor channel material nanosheet 22. The first dopant that is present in the bottom source/drain regions 46 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “N-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the bottom source/drain regions 44 can have a dopant concentration of from 4×10²⁰ atoms/cm³ to 3×10²¹ atoms/cm³.

After bottom source/drain region 46 formation, the first frontside ILD layer 48 is formed. The first frontside ILD layer 48 is composed of a dielectric material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0 (all dielectric constants mentioned herein are relative to a vacuum unless otherwise noted). The first frontside ILD layer 48 can be formed by a deposition process including, but not limited to, CVD, PECVD or spin-on coating. A recess etch typically follows the deposition process. The first frontside ILD layer 48 is formed on physically exposed surfaces (including a topmost surface and sidewall surfaces) of each bottom source/drain region 46. The first frontside ILD layer 48 has a height that does not extend to the bottommost surface of the bottommost second semiconductor channel material nanosheet 28.

Next, the top source/drain regions 50 are formed. The top source/drain regions 50 are typically formed by an epitaxial growth process. A recess etch can follow the epitaxial growth process. The top source/drain regions 50 extend outward from a sidewall of each second semiconductor channel material nanosheet 28. The top source/drain regions 50 are located on an upper surface of the first frontside ILD layer 48. The first frontside ILD layer 48 thus separates the bottom source/drain regions 46 from the top source/drain regions 50. Each top source/drain region 50 is composed of a semiconductor material and a second dopant. The semiconductor material that provides each top source/drain region 50 is composed of one of the semiconductor materials mentioned above for the first semiconductor layer 10. The semiconductor material that provides the top source/drain regions 50 can be compositionally the same, or compositionally different from each second semiconductor channel material nanosheet 28. The second dopant that is present in the top source/drain regions 50 can be either a p-type dopant or an n-type dopant, both of which have been defined above. The second dopant can be the same as, or different from, the first dopant. In one example, the first dopant is an n-type dopant, and the second dopant is a p-type dopant. In another example, the first dopant is a p-type dopant, and the second dopant is an n-type dopant. In yet another example, the first dopant and the second dopant are both n-type. In yet a further example, the first dopant and the second dopant are both p-type. Each of the top source/drain regions 50 can have a dopant concentration of from 4×10²⁰ atoms/cm³ to 3×10²¹ atoms/cm³. The present application thus contemplates forming stacked FETs including. for example, pFETs over nFETs, nFETs over pFETs, pFETs over pFETs, or nFETs over nFETs.

The second frontside ILD layer 52 is then formed on physically exposed surfaces (including topmost and sidewall surfaces) of the topmost source/drain regions 50 and on a topmost surface of the first frontside ILD layer 48. The second frontside ILD layer 52 can include one of the dielectric materials mentioned above for the first frontside ILD layer 48. The dielectric material that provides the second frontside ILD layer 52 can be compositionally the same as, or compositionally different from, the dielectric material that provides the first frontside ILD layer 48. The second frontside ILD layer 52 can be formed utilizing a deposition process such as mentioned above for forming the first frontside ILD layer 48. A planarization process such as, for example, chemical mechanical polishing (CMP) follows the deposition process that provides the second frontside ILD layer 52. The planarization process removes the sacrificial gate cap 32 (if the same is present) and an upper portion of each gate spacer 38. The sacrificial gate structures 30 are physically exposed after this planarization process has been performed.

The physically exposed sacrificial gate structures 30 are removed utilizing any material removal process such as, for example, etching, which is selective in removing the sacrificial gate structures 30. The removal of the sacrificial gate structures 30 reveals each of the patterned nanosheet containing structures. Next, each first sacrificial semiconductor material nanosheet 20 and each second sacrificial semiconductor material nanosheet 26 are removed so as to suspend each first semiconductor channel material nanosheet 22 and each second semiconductor channel material nanosheet 28 within each patterned nanosheet containing structure. The removal of the first sacrificial semiconductor material nanosheets 20 and second sacrificial semiconductor material nanosheets 26 includes any material removal process such as, for example, etching, which is selective in removing the first sacrificial semiconductor material nanosheets 20 and second sacrificial semiconductor material nanosheets 26.

Gates structures 54 are then formed. The gate structures 54 include a gate dielectric material and a gate electrode, both of which are not separately shown, but intended to be within region defined by the gate structures 54. As is known to those skilled in the art, the gate dielectric material directly contacts a physically exposed surface(s) of each semiconductor channel material nanosheet, and the gate electrode is formed on the gate dielectric material. The gate dielectric material has a dielectric constant of 4.0 or greater. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg).

The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations and thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co). The gate structures 54 can be formed by deposition of the gate dielectric material, and gate electrode material, followed by a planarization process. At this point of the present application, the gate structures 54 have a topmost surface that is coplanar with a topmost surface of the second frontside ILD layer 52.

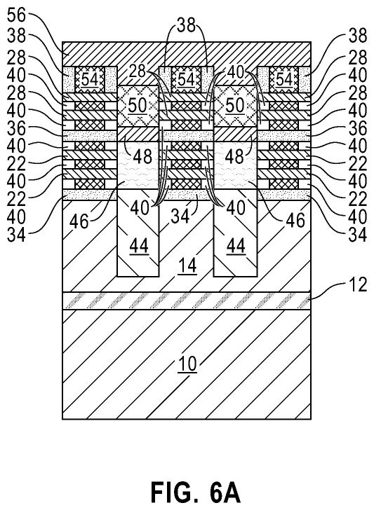

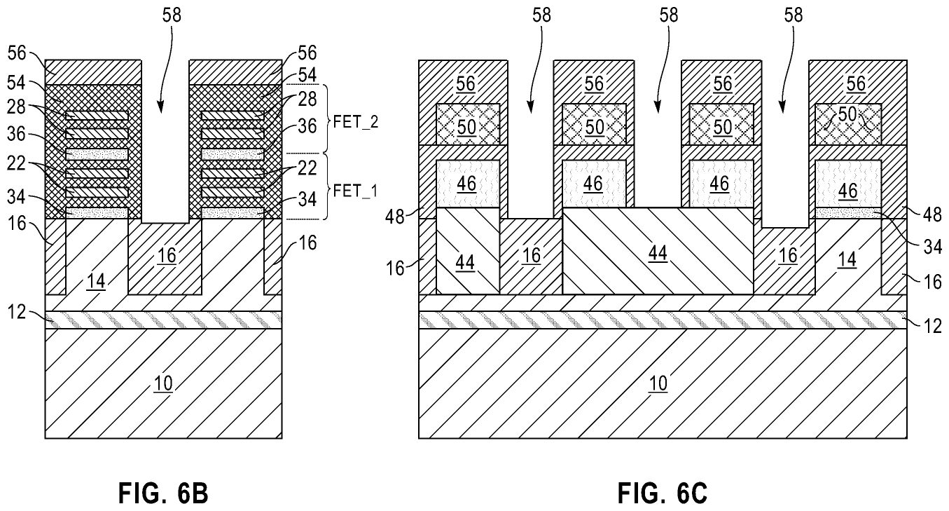

Referring now to FIGS. 6A, 6B and 6C, there are illustrated the exemplary semiconductor structure shown in FIGS. 5A, 5B and 5C, respectively, after forming a third frontside ILD layer (not specifically labeled; collectively, the second frontside ILD layer 52 and the third frontside ILD dielectric layer provide a middle-of-the-line (MOL) dielectric layer 56), and cutting at least one gate structure 54. The third frontside ILD layer can include one of the dielectric materials mentioned above for the first frontside ILD layer 48. The dielectric material that provides the third frontside ILD layer can be compositionally the same as, or compositionally different from, the dielectric material that provides the first frontside ILD layer 48 and/or the second frontside ILD layer 52. The third frontside ILD layer can be formed utilizing a deposition process such as mentioned above for forming the first frontside ILD layer 48. A planarization process such as, for example, chemical mechanical polishing (CMP) follows the deposition process that provides the third frontside ILD layer.

The at least one gate structure 54 can be cut utilizing any gate cut process that includes lithography and etching. The etch forms gate cut openings 58 as illustrated in FIGS. 6B and 6C of the present application. The etch can include RIE. It is noted that the gate cutting occurs in between the different active areas, AA, shown in FIG. 1. Some of the gate cut openings 58 physically exposed sacrificial material structures 44 that contacts the bottom source/drain region 48 present in adjacent active areas.

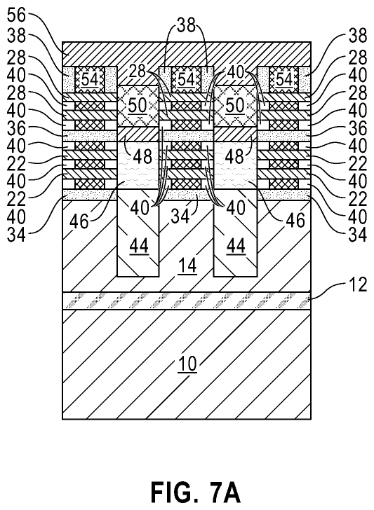

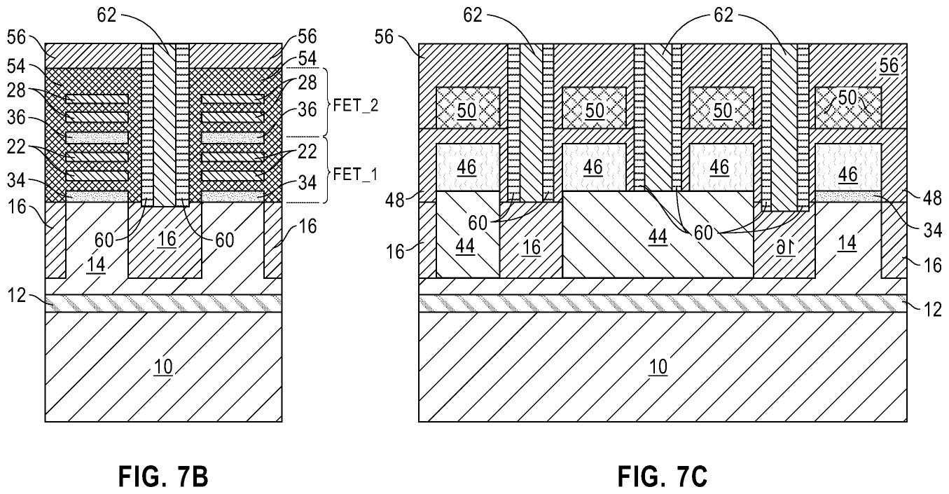

Referring now to FIGS. 7A, 7B and 7C, there are illustrated the exemplary semiconductor structure shown in FIGS. 6A, 6B and 6C, respectively, after forming a bi-layered dielectric structure including an outer dielectric liner 60 and an inner dielectric plug 62 in each gate cut opening 58. The outer dielectric liner 60 is composed of a first dielectric material and the inner dielectric plug 62 can be composed of a second dielectric material that is compositionally different from the first dielectric material. In one example, the first dielectric material is composed of silicon nitride and the second dielectric material is composed of silicon dioxide. The bi-layered dielectric structure can be formed by first depositing a layer of the first dielectric material. A directional etch can then be employed to remove the first dielectric material from the bottom of each gate cut opening 58 and from the topmost horizontal surface of the structure. The first deposition and the directional etch provide the outer dielectric liner 60. A layer of the second dielectric material is then deposited in a remaining volume of each gate cut opening 58 and atop the structure, and thereafter a planarization process is used to remove the second dielectric material that is formed outside of gate cut opening 58. The deposition of the second dielectric material, followed by the planarization step provide the inner dielectric plug 62. In some regions of the structure, the bi-layered dielectric structure lands on a surface of one of the shallow trench isolation structures 16, while in other regions of the structure the bi-layered dielectric structure lands on a sacrificial material structure 44 that contacts the bottom source/drain region 46 present in adjacent active areas.

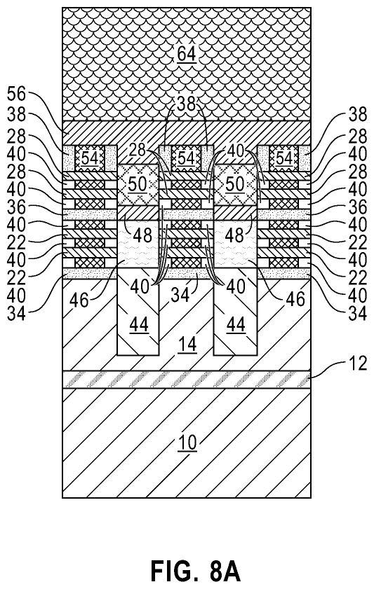

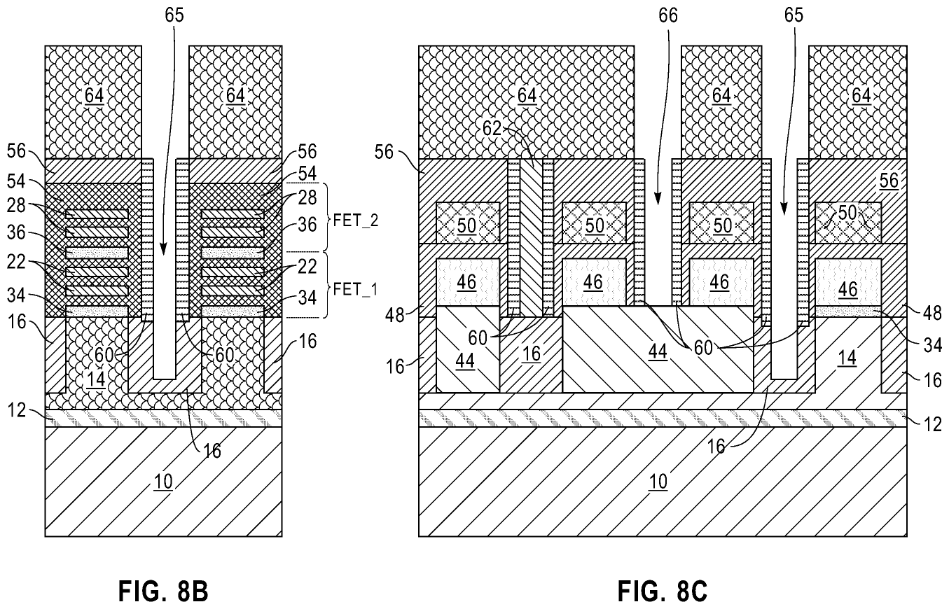

Referring now to FIGS. 8A, 8B and 8C, there are illustrated the exemplary semiconductor structure shown in FIGS. 7A, 7B and 7C, respectively, after forming deep via openings 65, 66 in the structure by removing the inner dielectric plug 62 from some of the bi-layered dielectric structures. The forming of the deep via openings 65, 66 includes first forming a patterned OPL layer 64 on the surface of the structure. The patterned OPL layer 64 includes openings that would be used in forming the deep via openings 65, 66. The patterned OPL layer 64 can be formed by lithography and etching. The openings in the patterned OPL layer 64 are aligned over the inner dielectric plug 62 from some of the bi-layered dielectric structures. The inner dielectric plugs 62 of the bi-layered dielectric structures that are not protected by the patterned OPL 64 are then removed utilizing an etching process that is selective in removing the inner dielectric plug 62 as compared to the outer dielectric liner 60. In some cases, this etching process can also remove an upper portion of the shallow trench isolation structure 16 as is shown in FIGS. 8B and 8C to form the deep via opening 65, while in other cases and as shown in FIG. 8B this etching process can stop on a topmost surface of the sacrificial material structure 44 that contacts the bottom source/drain region 46 present in adjacent active areas to form the deep via opening 66. Deep via opening 65 is a deeper via opening than deep via opening 66.

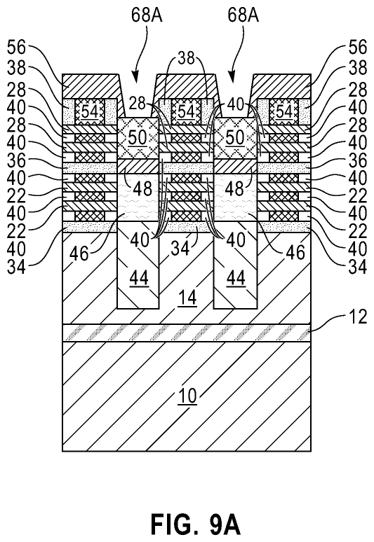

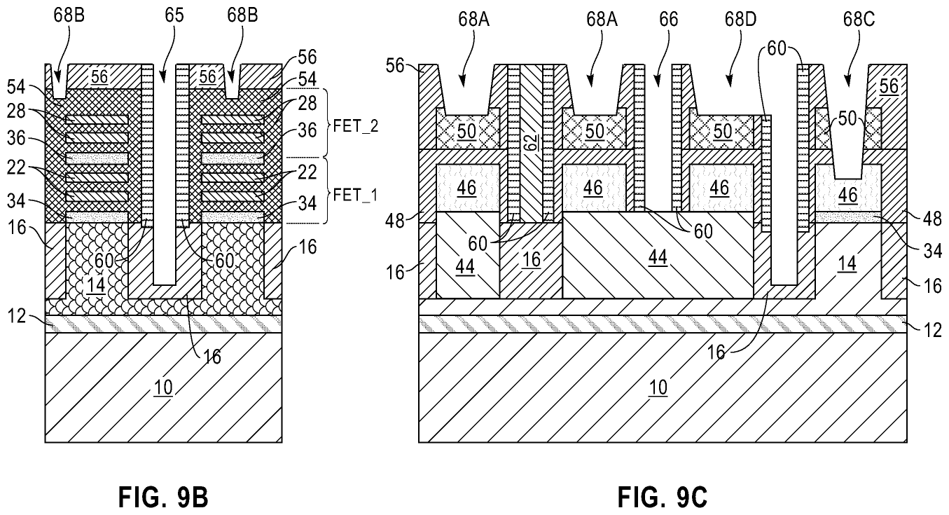

Referring now to FIGS. 9A, 9B and 9C, there are illustrated the exemplary semiconductor structure shown in FIGS. 8A, 8B and 8C, respectively, after forming frontside contact openings into the MOL dielectric layer 56. Prior to forming the frontside contact openings, the patterned OPL layer 64 is removed from the structure utilizing any material removal process that is selective in removing the patterned OPL layer 64. The frontside contact openings can be formed by lithography and etching. The frontside contact openings that are formed include top source/drain contact opening 68A, gate contact openings 68B, bottom source/drain contact openings 68C, and a merged contact opening 68D. Merged contact opening 68D includes a combination of a top source/drain contact opening and deep via opening 65.

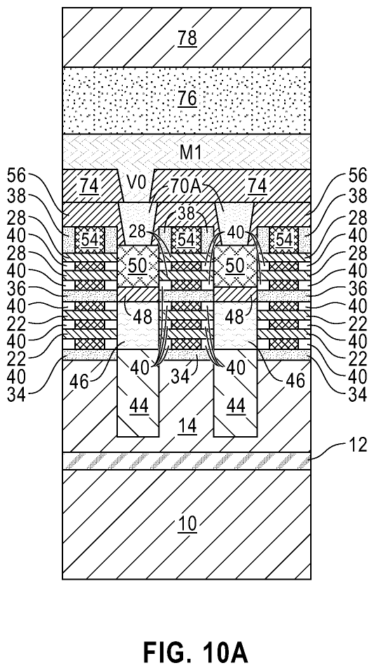

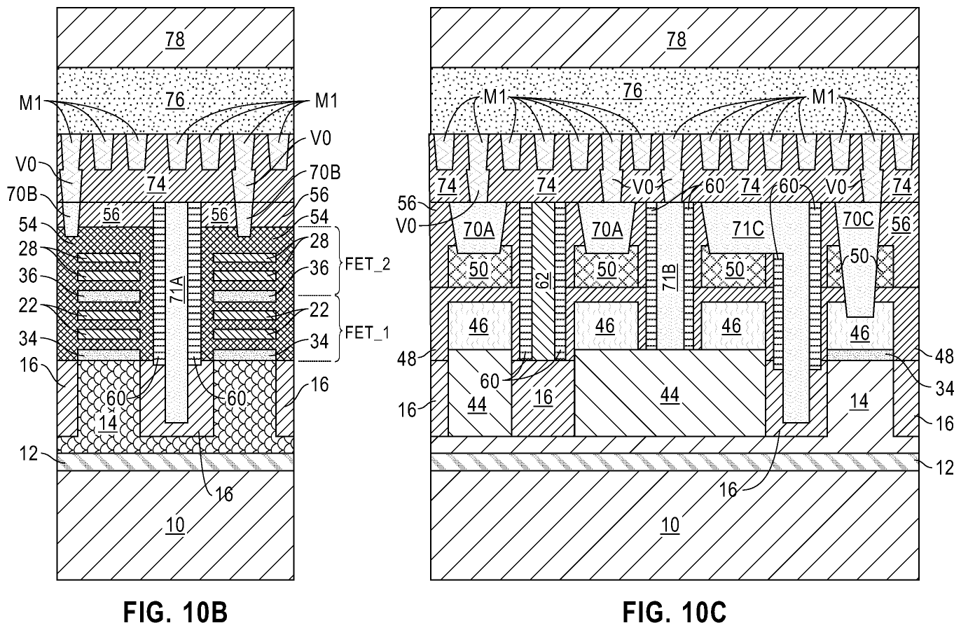

Referring now to FIGS. 10A, 10B and 10C, there are illustrated the exemplary semiconductor structure shown in FIGS. 9A, 9B and 9C, respectively, after forming frontside contact structures and deep vias, an initial frontside BEOL structure including lower interconnect levels, an additional frontside BEOL structure, and a carrier wafer. The frontside contact structures and the deep vias are formed into each of the contact openings and deep via openings shown in FIGS. 9A, 9B and 9C utilizing a metallization process that includes filling (including deposition and planarization) each of the frontside contact openings and deep via openings with at least a contact conductor material. The contact conductor material can include, for example, a silicide liner, such as Ni, Pt, NiPt, an adhesion metal liner, such as TiN, and conductive metals such as W. Cu, Al, Co, Ru, Mo, Os, Ir, Rh, or an alloy thereof. The frontside contact structures can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

The metallization forms top source/drain contact structures 70A, top gate contact structures 70B, combined top and bottom source/drain contact structures 70C, first deep via 71A, second deep via 71B and a combined top source/drain contact structure/deep via 71C. In the present application, each top source/drain structure 70A contacts one of the top source/drain regions 50, each top gate contact structure 70B contacts one of the gate structures 54, and each combined top and bottom source/drain contact structure 70C contacts both a top source/drain region 50 and a bottom source/drain region 46. In the present application, the term “deep via” is used to denote a contact conductor material-containing structure that is present in a via opening.

In the present application, the first deep via 71A and the combined top source/drain contact structure/deep via 71C land on a subsurface of one of the shallow trench isolation structures 16, and the second deep via 71B lands on a surface of one of the sacrificial material structures 44. In the present application, the outer dielectric liner 60 is present on a sidewall of each of the first deep via 71A, the second deep via 71B and the combined top source/drain contact structure/deep via 71C. In the present application, a lower portion of the first deep via 71A is present in one of the shallow trench isolation structures 16, a middle portion of the first deep via 71A is located laterally adjacent to two neighboring gate structures 54, and a top portion of the first deep via 71A is located in the MOL dielectric layer 56. In the present application, the second deep via 71B is present between the bottom and top source/drain regions of two neighboring gate structures 54. In the present application, a lower portion of the combined top source/drain contact structure/deep via 71C is present in one of the shallow trench isolation structures 16, a middle portion of the combined top source/drain contact structure/deep via 71C is located laterally adjacent to two neighboring gate structures 54, and a top portion of the combined top source/drain contact structure/deep via 71C is located in the MOL dielectric layer 56.

The initial frontside BEOL structure including lower interconnect levels is then formed. The initial frontside BEOL structure includes a fourth frontside ILD layer 74 and wiring structures including a first via structure, V0, and a first metal line, M1. The V0 are typically merged with one of the M1s. The fourth frontside ILD layer 74 is composed of one of the dielectric materials mentioned above for the first frontside ILD layer 48. The fourth frontside ILD layer 74 is formed via a deposition process on the MOL dielectric layer 56 and each of the frontside contact structures and deep vias that are present in the structure shown in FIGS. 9A-9C. The wiring structures including the first via structure, VO, and the first metal line, M1 are composed of at least an electrically conductive metal or electrically conductive metal alloy. In some embodiments, Cu or a Cu—Al alloy can be used as the electrically conductive material that provides the wiring structures including the first via structure, VO, and the first metal line, M1, that are present in the initial frontside BEOL structure. The wiring structure present in the initial frontside BEOL structure are formed utilizing a metallization process that includes forming openings into the fourth frontside ILD layer 74, filling each opening with an electrically conductive material, and then performing a planarization process.

The additional frontside BEOL structure 76 is then formed on the initial frontside BEOL structure. The additional frontside BEOL structure 76 can include one or more interconnect dielectric material layers (including one of the dielectric materials mentioned above for the first frontside ILD layer 48) that contain frontside metal wires (the metal wires can be composed of any electrically conductive metal or electrically conductive metal alloy) embedded therein. The additional frontside BEOL structure 76 can include “x” numbers of frontside metal levels, wherein “x” is an integer starting from 1. The additional frontside BEOL structure 76 can be formed utilizing techniques well known to those skilled in the art.

As is illustrated in FIGS. 10A-10C, the wiring structures including the first via structure, V0, and the first metal line, M1, are used in connecting the top source/drain contact structures 70A, the top gate contact structures 70B, the first deep via 71A, and the second deep via 71B to the additional frontside BEOL structure 76. The combined top source/drain contact structure/via bar power 71C is not however connected to any wiring structures present in the initial frontside BEOL structure and thus is not directly connected to the additional BEOL structure 76.

The carrier wafer 78 can include one of the semiconductor materials mentioned above for the first semiconductor layer 10. Carrier wafer 78 is bonded to the additional frontside BEOL structure 78 after additional frontside BEOL structure 76 formation.

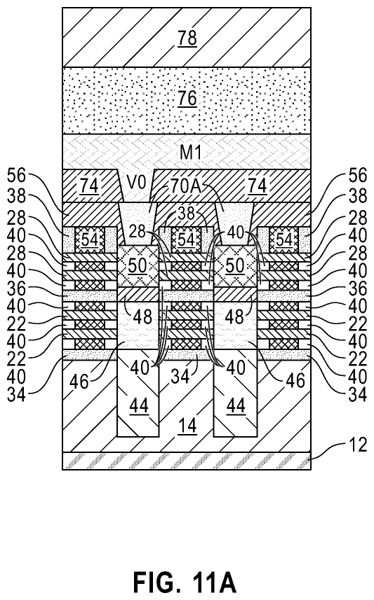

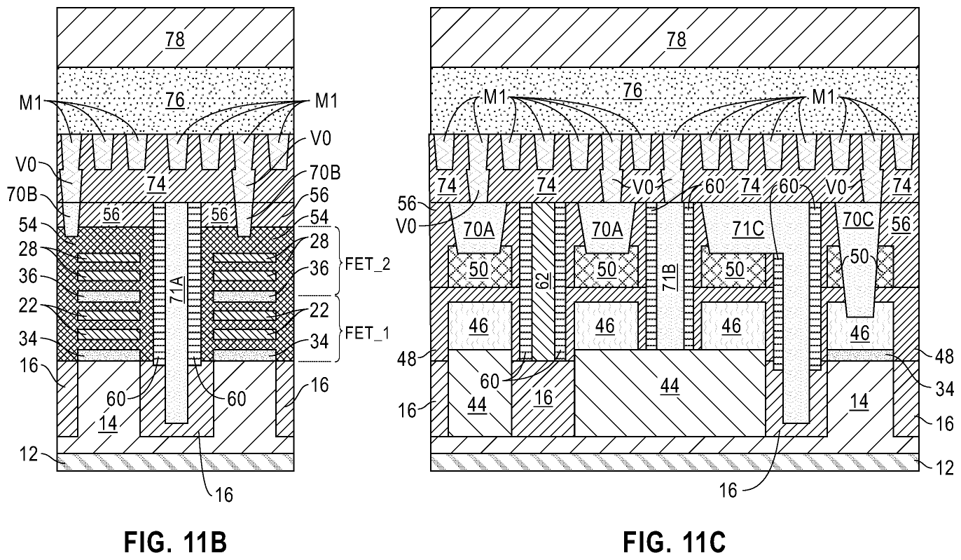

Referring now to FIGS. 11A, 11B and 11C, there are illustrated the exemplary semiconductor structure shown in FIGS. 10A, 10B and 10C, respectively, after removing the first semiconductor layer 10 of the substrate (10/12/14) to expose the etch stop layer 12 of the substrate (10/12/14). The removal of the first semiconductor layer 10 typically includes flipping the wafer 180° to physically expose a backside of the substate. This flipping step is not shown in the drawings of the present application for clarity. In the illustrated embodiment, the substrate includes the first semiconductor layer 10, the etch stop layer 12, and the second semiconductor layer 14. Thus, the flipping can physically expose the first semiconductor layer 10 of the substrate (10/12/14). This flipping step will allow backside processing of the exemplary structure. In the present application the backside of the wafer can be defined as the area of the wafer that is beneath the bottom dielectric isolation layer 34. Flipping of the structure can be performed by hand or by utilizing a mechanical means such as, for example, a robot arm.

In the illustrated embodiment, the removal of the physically exposed first semiconductor layer 10 physically exposes the etch stop layer 12. The removal of the first semiconductor layer 10 can be performed utilizing a material removal process that is selective in removing the first semiconductor material that provides the first semiconductor layer 10.

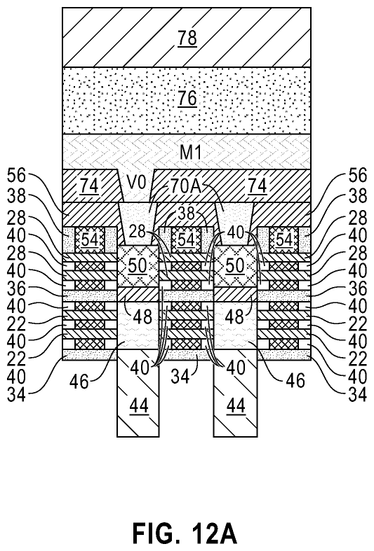

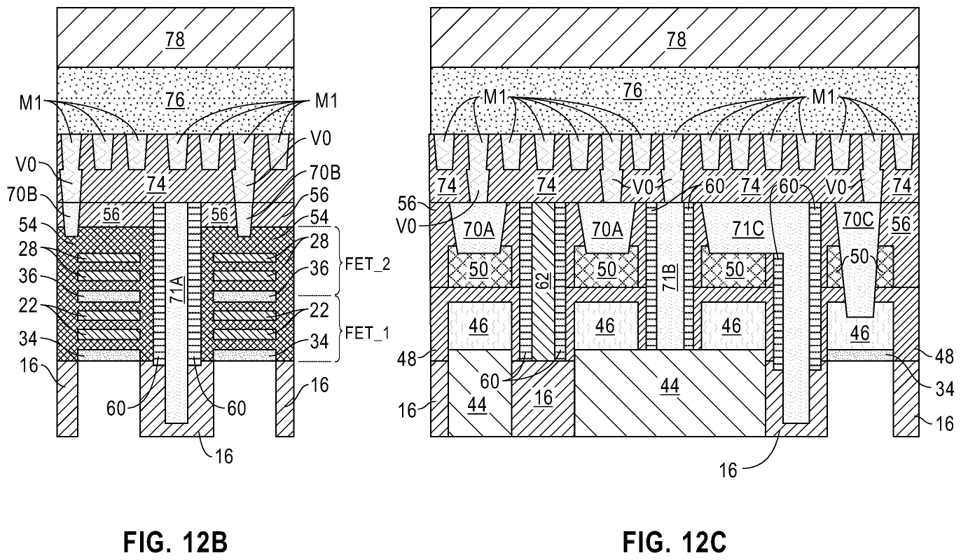

Referring now to FIGS. 12A, 12B and 12C, there are illustrated are cross sectional views of the exemplary semiconductor structure shown in FIGS. 11A, 11B and 11C, respectively, after removing the etch stop layer 12 and a second semiconductor layer 14 of the substrate (10/12/14). The removal of the etch stop layer 12 includes a material removal process that is selective in removing the etch stop layer 12. The removal of the etch stop layer 12 physically exposes the second semiconductor layer 14 of the substrate (10/12/14). The physically exposed second semiconductor layer 14 can be removed utilizing a material removal process that is selective in removing that layer from the structure. Other material removal processes can be used depending on the type of substrate used. For example, in some embodiments in which substrate is a composed entirely of one semiconductor material, one material removal process can be used instead of the multiple material removal processing steps described herein. As is illustrated in FIGS. 12A-12C, the removal of the substrate (10/12/14) reveals a surface of each sacrificial material structure 44 and a surface of each bottom dielectric isolation layer 34.

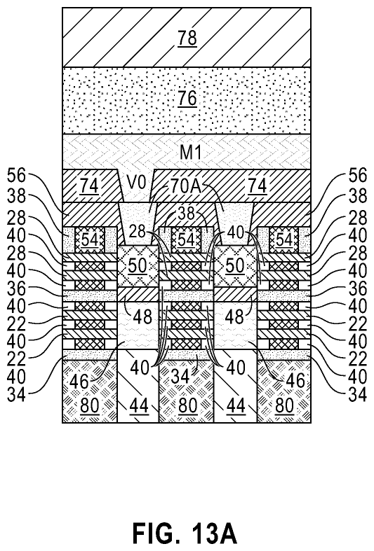

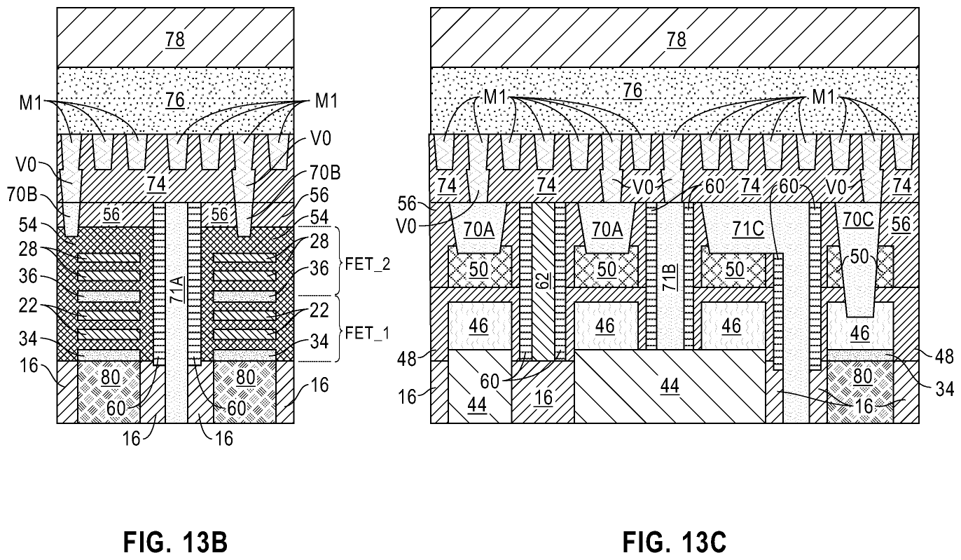

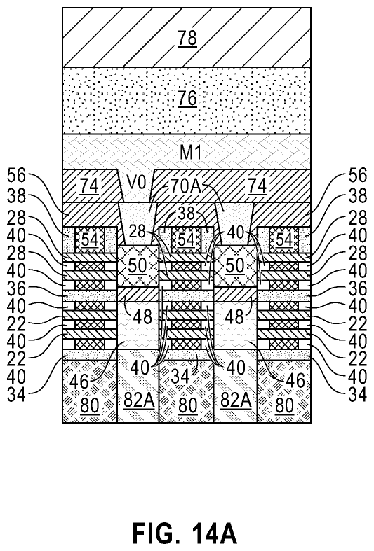

Referring now to FIGS. 13A, 13B and 13C, there are illustrated the exemplary semiconductor structure shown in FIGS. 12A, 12B and 12C, respectively, after forming a first backside interlayer dielectric (ILD) layer 80. The first backside ILD layer 80 includes one of the dielectric materials mentioned above for the first frontside ILD layer 48. The first backside ILD layer 80 can be formed by a deposition process. A planarization process can follow the deposition that provides the dielectric material of the first backside ILD layer 80. As is illustrated, the first backside ILD layer 80 contacts a physically exposed surface of each of the bottom dielectric isolation layers 34 and the first backside ILD layer 80 is located adjacent to the sacrificial material structures 44 and shallow trench isolation structures 16. Each dielectric structure 44 has a surface that is physically exposed as is shown in FIGS. 13A-13C.

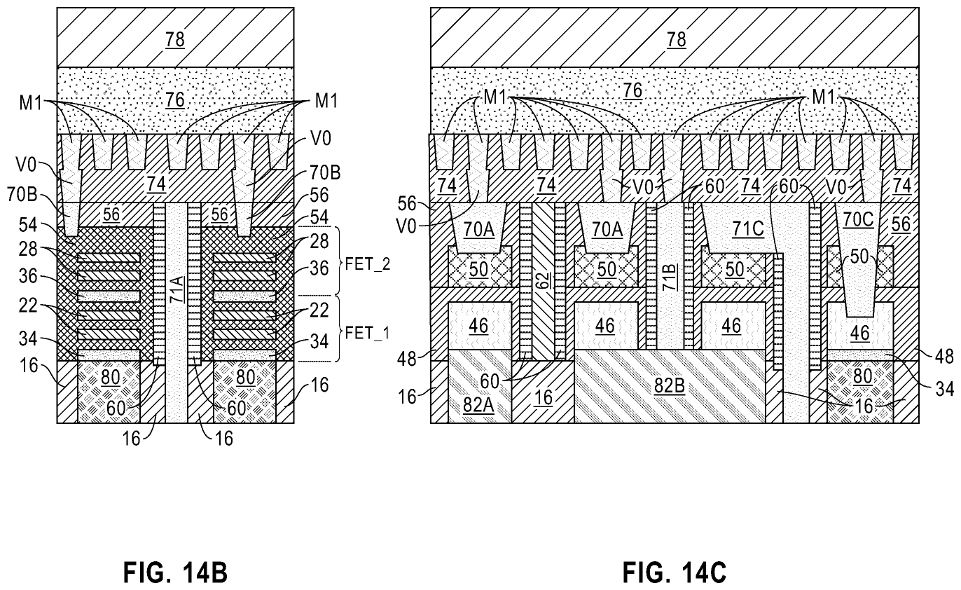

Referring now to FIGS. 14A, 14B and 14C, there are illustrated the exemplary semiconductor structure shown in FIGS. 13A, 13B and 13C, respectively, after removing each sacrificial material structure 44 and forming backside source/drain contact structures 82A, 82B. The removal of the sacrificial material structures 44 can be performed utilizing an etching process that is selective in removing the dielectric material that provides the sacrificial material structures 44. Backside source/drain contact structures 82A, 82B are then formed in the voids created by removing the sacrificial material structures 44. The backside source/drain contact structures 82A, 82B include one of the contact conductor materials defined above for the frontside contact structures and can be formed utilizing a metallization process. Backside source/drain contact structures 82A contact a single bottom source/drain region 46, while backside source/drain contact structure 82B contacts the bottom source/drain region 46 present in adjacent active areas.

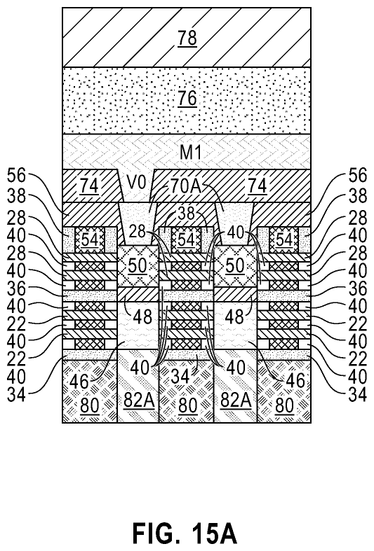

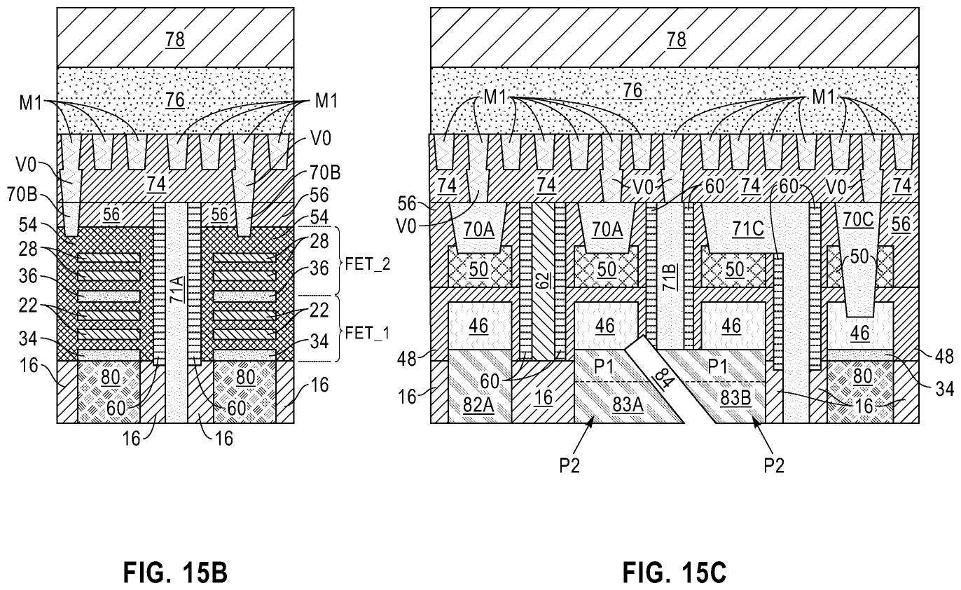

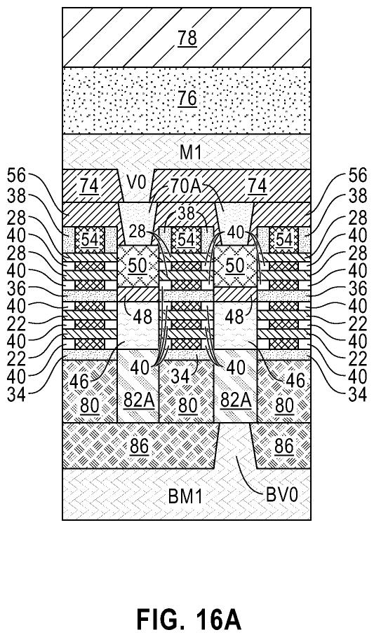

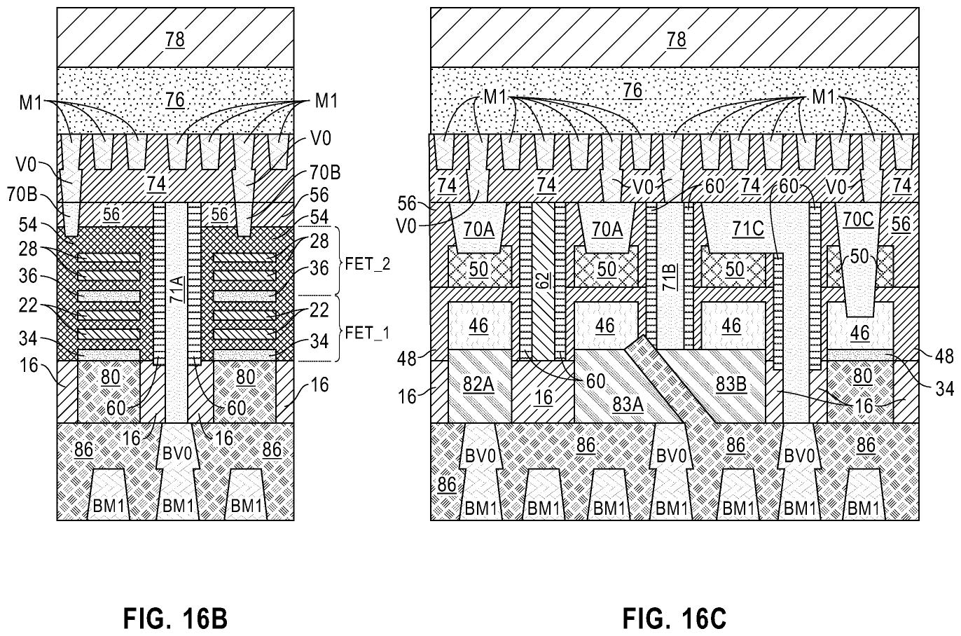

Referring now to FIGS. 15A, 15B and 15C, there are illustrated the exemplary semiconductor structure shown in FIGS. 14A, 14B and 14C, respectively, after performing a backside angle cut of one of the backside source/drain contact structures. In the present application, the backside angle cut is performed on the backside source/drain contact structure 82B that contacts the bottom source/drain region 46 present in adjacent active areas. The backside angle cut forms angle cut region 84 and splits backside source/drain contact structure 82B into a first backside source/drain contact structure 83A and a second backside source/drain contact structure 83B. As is illustrated in FIG. 15C, the angled cut region 84 laterally separates the first backside source/drain contact structure 83A from the second backside source/drain contact structure 83B. As is also illustrated in FIG. 16C, the angled cut region 84 contacts a lower portion (including bottommost surface and sidewall) surface of the bottom source/drain region 46 that the first backside source/drain contact structure 83A is in contact with.

The first backside source/drain contact structure 83A includes a first portion, P1, having a first critical dimension, CD1, and a second portion, P2, having a second critical dimension CD2, wherein the first critical dimension is less than the second critical dimension. The second backside source/drain contact structure 83B includes a first portion, P1, having a first critical dimension, CD1, and a second portion, P2, having a second critical dimension, CD2, wherein the first critical dimension is greater than the second critical dimension.

Referring now to FIGS. 16A, 16B and 16C, there are illustrated the exemplary semiconductor structure shown in FIGS. 15A, 15B and 15C, respectively, after forming an initial backside BEOL structure including lower interconnect levels. The initial backside BEOL structure including lower interconnect levels is then formed. The initial backside BEOL structure includes a second backside ILD layer 86 and wiring structures including a first backside via structure, BV0, and a first backside metal line, BM1. The second backside ILD layer 86 is composed of one of the dielectric materials mentioned above for the first frontside ILD layer 48. The second backside ILD layer 86 is formed via a deposition process. The wiring structures including the first backside via structure, BV0, and the first backside metal line, BM1 are composed of at least an electrically conductive metal or electrically conductive metal alloy. In some embodiments, Cu or a Cu—Al alloy can be used as the electrically conductive material that provides the wiring structures including the first backside via structure, BV0, and the first backside metal line, BM1, that are present in the initial backside BEOL structure. The wiring structure present in the initial backside BEOL structure are formed utilizing a metallization process that includes forming openings into the second backside ILD layer 86, filling each opening with an electrically conductive material, and then performing a planarization process.

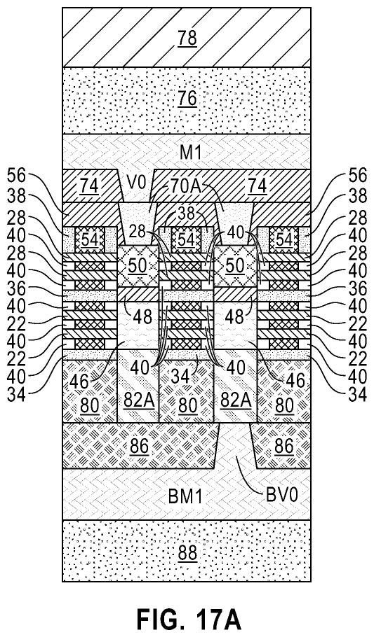

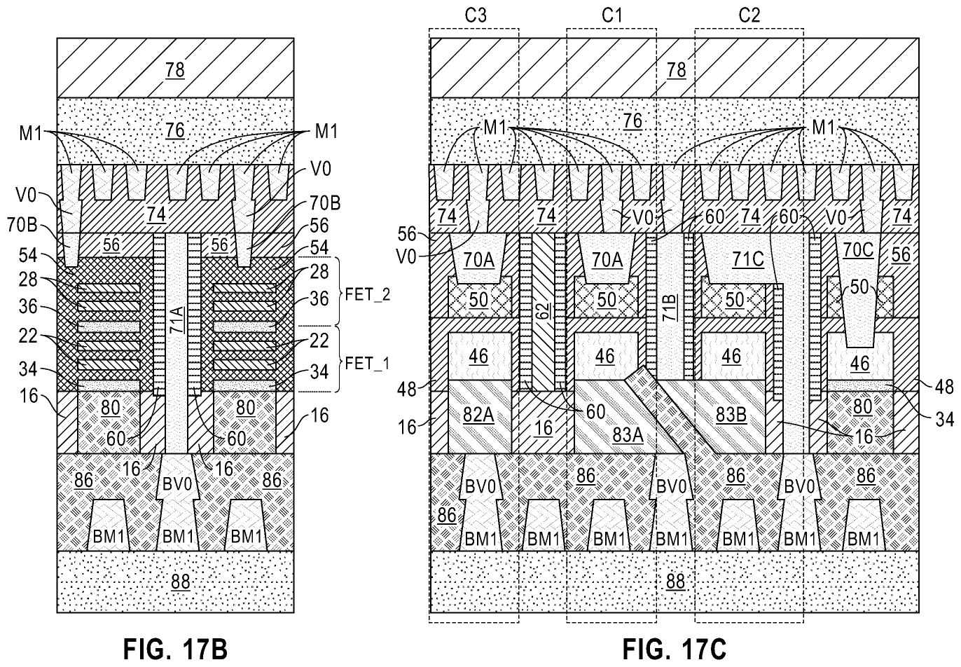

Referring now to FIGS. 17A, 17B and 17C, there are illustrated the exemplary semiconductor structure shown in FIGS. 16A, 16B and 16C, respectively, after forming an additional backside BEOL structure. Additional backside BEOL structure 88 is then formed on the initial backside BEOL structure. The additional backside BEOL structure 88 can include one or more interconnect dielectric material layers (including one of the dielectric materials mentioned above for the first frontside ILD layer 48) that contain frontside metal wires (the metal wires can be composed of any electrically conductive metal or electrically conductive metal alloy) embedded therein. The additional backside BEOL structure 88 can include “y” numbers of backside metal levels, wherein “y” is an integer starting from 1. The additional backside BEOL structure 88 can be formed utilizing techniques well known to those skilled in the art.

Notably, FIGS. 17A, 17B and 17C illustrates a semiconductor structure in accordance with an embodiment of the present application. The semiconductor structure includes a first stacked FET cell, C1, including a second FET, FET_2, stacked over a first FET, FET_1. The structure further includes a second stacked FET cell, C2, located adjacent to the first stacked FET cell, C1, and including a fourth FET, FET_4 stacked over a third FET, FET_3; See FIG. 17B. Note that FET_3 and FET_4 are not specifically shown in FIG. 17B, nor do the labels FET_3 and FET_4 appear in any of the drawings. FET_3 and FET_4 would look similar to FET_1 and FET_2 shown in FIG. 17B. The structure even further includes first backside source/drain contact structure 83A located beneath the first stacked FET cell, C1, and contacting a source/drain region (i.e., bottom source/drain region 40) of the first FET, FET_1, second backside source/drain contact structure 83B located beneath the second stacked FET cell, C2, and contacting a source/drain region (i.e., the bottom source/drain region 40) of the third FET, FET_3, and angled cut region 84 (now filled with a backside ILD material) laterally separating the first backside source/drain contact structure 83A from the second backside source/drain contact structure 83B.

In embodiments of the present application, and as mentioned above. the first backside source/drain contact structure 83A includes a first portion, P1, having a first critical dimension, and a second portion, P2, having a second critical dimension, wherein the first critical dimension is less than the second critical dimension. As is illustrated, the first portion, P1, of the first backside source/drain contact structure 83A is in contact with the source/drain region (i.e., bottom source/drain region 40) of the first FET, FET_1, and the second portion, P2, of the first backside source/drain contact structure 83A is electrically connected to additional backside BEOL structure 88 by the backside wiring structures, BV0 and BM1, present in the initial backside BEOL structure.

In embodiments of the present application, and as is mentioned above, the second backside source/drain contact structure 83B includes a first portion, P1, having a first critical dimension, and a second portion, P2, having a second critical dimension, wherein the first critical dimension is greater than the second critical dimension. As is illustrated, the second portion, P2, of the second backside source/drain contact 83B is in contact with the source/drain region (bottom source/drain region 40) of the third FET, FET_3.

In embodiments of the present application, the structure includes the initial frontside BEOL structure and the additional frontside BEOL structure 76 above both the first stacked FET cell, C1, and the second stacked FET cell, C2, wherein the source/drain region (i.e., bottom source/drain region 46) of the third FET, FET_3, is electrically connected to the additional frontside BEOL structure 76 by second deep via 71B and frontside metal wiring structures present in the initial frontside BEOL structure.

In embodiments of the present application, the second deep via 71B is a vertical extending pillar located laterally between the first stacked FET cell, C1, and the second stacked FET cell, C2. In embodiments, outer dielectric liner 62 is present on a sidewall of the second deep via 71B.

In embodiments of the present application, a source/drain region (top source/drain region 50 of the second transistor, FET_2, is electrically connected to the additional frontside BEOL 76 structure by other frontside metal wiring structures, i.e., V0 and M1, present in the initial frontside BEOL structure.

In embodiments of the present application, a source/drain region (i.e., top source/drain region 50) of the fourth transistor, FET_4, is electrically connected to the additional backside BEOL structure 76 by combined top source/drain contact structure/deep via 71C, and other backside wiring structures, BV0 and BM1, present in the initial backside BEOL structure.

In embodiments, combined top source/drain contact structure/dep via 71C includes a frontside source/drain contact structure merged with deep via.

In embodiments, the first backside source/drain contact structure 83A has an angled sidewall facing an angled sidewall of second backside source/drain contact structure 83B. In embodiments, each of the first backside source/drain contact structure 83A and the second backside source/drain contact structure 83B has a perpendicular sidewall opposite the angled sidewall.

In embodiments, the first FET, FET_1, and the second FET, FET_2, share a common gate structure 54, and the third FET, FET_3, and the fourth FET, FET_4, share a common gate structure 54.

In embodiments, a third stacked FET cell, C3, is located adjacent to the first stacked FET cell, C1, wherein the first stacked FET cell and the third stacked FET cell are separated by bilayer sacrificial material structure including outer dielectric liner 60 and inner dielectric plug 62.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
a first stacked field effect transistor (FET) cell comprising a second FET stacked over a first FET;
a second stacked FET cell located adjacent to the first stacked FET cell and comprising a fourth FET stacked over a third FET;
a first backside source/drain contact structure located beneath the first stacked FET cell and contacting a source/drain region of the first FET;
a second backside source/drain contact structure located beneath the second stacked FET cell and contacting a source/drain region of the third FET; and
an angled cut region laterally separating the first backside source/drain contact structure from the second backside source/drain contact structure.

2. The semiconductor structure of claim 1, wherein the angled cut region is filled with a backside interlayer dielectric material.

3. The semiconductor structure of claim 2, wherein the backside interlayer dielectric material contacts a corner of the source/drain region of the first transistor.

4. The semiconductor structure of claim 1, wherein the first backside source/drain contact structure comprises a first portion having a first critical dimension, and a second portion having a second critical dimension, wherein the first critical dimension is less than the second critical dimension.

5. The semiconductor structure of claim 4, wherein the first portion of the first backside source/drain contact structure having the first critical dimension is in contact with the source/drain region of the first FET, and the second portion of the first backside source/drain contact structure is electrically connected to an additional backside backend-of-the line (BEOL) structure by backside wiring structures present in an initial backside BEOL structure.

6. The semiconductor structure of claim 1, wherein the second backside source/drain contact structure comprises a first portion having a first critical dimension, and a second portion having a second critical dimension, wherein the first critical dimension is greater than the second critical dimension.

7. The semiconductor structure of claim 6, wherein the second portion of the second backside source/drain contact is in contact with the source/drain region of the third FET.

8. The semiconductor structure of claim 1, further comprising an initial frontside BEOL structure and an additional frontside BEOL structure above both the first stacked FET cell and the second stacked FET cell, wherein the source/drain region of the third FET is electrically connected to the additional frontside BEOL structure by a deep via and frontside metal wiring structures present in the initial frontside BEOL structure.

9. The semiconductor structure of claim 8, wherein the deep via is a vertical extending pillar located laterally between the first stacked FET cell and the second stacked FET cell.

10. The semiconductor structure of claim 9, further comprising an outer dielectric liner present on a sidewall of the deep via.

11. The semiconductor structure of claim 8, wherein a source/drain region of the second transistor is electrically connected to the additional frontside BEOL structure by other frontside metal wiring structures present in the initial frontside BEOL structure.

12. The semiconductor structure of claim 8, wherein a source/drain region of the fourth transistor is electrically connected to the additional backside BEOL structure by a combined top source/drain contact structure/deep via, and other backside wiring structures present in the initial backside BEOL structure.

13. The semiconductor structure of claim 12, wherein the combined top source/drain contact structure/deep via comprises a frontside source/drain contact structure merged with a deep via.

14. The semiconductor structure of claim 8, further comprising a carrier wafer located on the frontside BEOL structure.

15. The semiconductor structure of claim 1, wherein the first FET, the second FET, the third FET and the fourth FET are each nanosheet FETs.

16. The semiconductor structure of claim 1, further comprising a bottom dielectric isolation layer located beneath the first FET and the third FET, and a device isolation layer separating the second FET from the first FET and the fourth FET from the third FET.

17. The semiconductor structure of claim 1, wherein the first backside source/drain contact structure has an angled sidewall facing an angled sidewall of second backside source/drain contact structure.

18. The semiconductor structure of claim 17, wherein each of the first backside source/drain contact structure and the second backside source/drain contact structure has a perpendicular sidewall opposite the angled sidewall.

19. The semiconductor structure of claim 1, wherein the first FET and the second FET share a common gate structure, and the third FET and the fourth FET share a common gate structure.

20. The semiconductor structure of claim 1, further comprising a third stacked FET cell located adjacent to the first stacked FET cell, wherein the first stacked PET cell and the third stacked FET cell are separated by a bilayer sacrificial material structure, the bilayer sacrificial material structure comprises an outer dielectric liner and an inner dielectric plug.
